(19) United States
(12) Patent Application Publication
(10) Pub. No.: US 2024/0274495 A1
(43) Pub. Date: Aug. 15, 2024

(54) ELECTRONIC PACKAGE AND MANUFACTURING METHOD THEREOF

(71) Applicant: SILICONWARE PRECISION INDUSTRIES CO., LTD., Taichung City (TW)

(72) Inventors: Shuai-Lin LIU, Taichung City (TW); Nai-Hao KAO, Taichung City (TW); Yu-Po WANG, Taichung City (TW)

(73) Assignee: SILICONWARE PRECISION INDUSTRIES CO., LTD., Taichung City (TW)

(21) Appl. No.: 18/345,753

(22) Filed: Jun. 30, 2023

(30) Foreign Application Priority Data
Feb. 14, 2023 (TW) 112105207

(51) Int. Cl. H01L 23/367; H01L 21/48

(52) U.S. Cl. CPC H01L 23/3677; H01L 21/4871

(57) ABSTRACT

An electronic package and a manufacturing method thereof are provided, in which a first electronic element and a second electronic element are embedded in a packaging layer, and a circuit structure is formed on the packaging layer and electrically connected to the first electronic element and the second electronic element, where the circuit structure has a heat dissipation portion thermally connected to the first electronic element. Therefore, the heat energy generated by the first electronic element can be quickly dissipated to the outside via the heat dissipation portion, so as to avoid the problem of affecting the operation of the second electronic element due to overheating of the packaging layer.

### BACKGROUND

### 1. Technical Field

The present disclosure relates to a semiconductor packaging process, and more particularly, to an electronic package with a heat dissipation mechanism and a manufacturing method thereof.

### 2. Description of Related Art

With the vigorous development of the electronic industry, electronic products are gradually developing towards the trend of multi-function and high performance. There are many technologies currently used in the field of chip packaging, such as Chip Scale Package (CSP), Direct Chip Attached (DCA), or Multi-Chip Module (MCM) and other flip-chip packaging modules.

FIG. 1 is a schematic cross-sectional view of a conventional semiconductor package 1. As shown in FIG. 1, in the conventional semiconductor package 1, a plurality of semiconductor chips 10, 11 are disposed on a package substrate 13 at intervals by a plurality of conductive bumps 14, so that a gap A is formed between any two adjacent ones of the semiconductor chips 10, 11, and the conductive bumps 14 are covered with an underfill 15, and the semiconductor chips 10, 11 and the underfill 15 are covered with a packaging layer 12.

By packaging the plurality of semiconductor chips 10, 11 into one chip module, the semiconductor package 1 has a large number of I/Os which can greatly increase the computing ability of the processor and reduce the delay time of signal transmission, so as to be applied to high-end products with high-density line/high transmission speed/high stacking number/large-size design.

However, in the conventional semiconductor package 1, the semiconductor chip 10 with high computing functions, such as a System-On-Chip (SoC), will generate a large amount of heat during operation. Therefore, when the semiconductor chips 10, 11 with different functions are integrated in the same packaging layer 12, the heat generated by the semiconductor chip 10 with high computing function will gather heat in the packaging layer 12 during operation, so that the packaging layer 12 will be overheated and affect the operation of the semiconductor chip 11 in other forms (such as memory).

Therefore, there is a need for a solution that addresses the aforementioned shortcomings in the prior art.

### SUMMARY

In view of the aforementioned shortcomings of the prior art, the present disclosure provides an electronic package, which comprises: a packaging layer; a first electronic element embedded in the packaging layer; a second electronic element embedded in the packaging layer and spaced apart from the first electronic element; and a circuit structure disposed on the packaging layer and electrically connected to the first electronic element and the second electronic element, wherein the circuit structure has a heat dissipation portion thermally connected to the first electronic element.

The present disclosure also provides a method for manufacturing an electronic package, the method comprises: embedding a first electronic element and a second electronic element in a packaging layer in a manner of being spaced apart from each other; and forming a circuit structure on the packaging layer, wherein the circuit structure is electrically connected to the first electronic element and the second electronic element, wherein the circuit structure has a heat dissipation portion thermally connected to the first electronic element.

In the aforementioned electronic package and method, the circuit structure includes an insulating layer, a circuit layer formed on the insulating layer, and a plurality of conductive blind vias formed in the insulating layer and electrically connected to the circuit layer and the first electronic element.

In the aforementioned electronic package and method, the heat dissipation portion includes a plurality of heat dissipation pillars stacked on each other.

In the aforementioned electronic package and method, the heat dissipation portion is a single heat dissipation pillar.

In the aforementioned electronic package and method, the heat dissipation portion further comprises at least one heat dissipation pillar and at least one heat dissipation layer thermally connected to the heat dissipation pillar.

In the aforementioned electronic package and method, the circuit structure has a ground wire connected to the heat dissipation portion.

In the aforementioned electronic package and method, the circuit structure is penetrated through by the heat dissipation portion.

In the aforementioned electronic package and method, the circuit structure is free from being penetrated through by the heat dissipation portion.

In the aforementioned electronic package and method, the first electronic element is provided with a heat dissipation body corresponding to the heat dissipation portion. For example, the heat dissipation body is a heat sink.

As can be understood from the above, in the electronic package and the manufacturing method thereof according to the present disclosure, the circuit structure is designed with the heat dissipation portion, so that the heat dissipation portion can be thermally connected to the first electronic element to enhance the heat dissipation effect of the first electronic element. Therefore, compared with the prior art, when the first electronic element has a high computing function, the heat energy generated during the operation of the first electronic element can be quickly dissipated to the outside via the heat dissipation portion, so as to avoid the problem of affecting the operation of the second electronic element due to overheating of the packaging layer.

### BRIEF DESCRIPTION OF THE DRAWINGS

FIG. 1 is a schematic cross-sectional view of a conventional semiconductor package.

FIG. 2A, FIG. 2B, FIG. 2C-1 and FIG. 2D are schematic cross-sectional views illustrating a method of manufacturing an electronic package according to the present disclosure.

FIG. 2C-2 is a schematic partially enlarged top view of FIG. 2C-1.

FIG. 2E is a schematic cross-sectional view of the subsequent process of FIG. 2D.

FIG. 3A, FIG. 3B and FIG. 3C are schematic cross-sectional views showing other different embodiments of FIG. 2D.

FIG. 4A to FIG. 4F are schematic top views of various shapes of a heat dissipation component in FIG. 2D.

### DETAILED DESCRIPTION

Implementations of the present disclosure are described below by embodiments. Other advantages and technical effects of the present disclosure can be readily understood by one of ordinary skill in the art upon reading the disclosure of this specification.

It should be noted that the structures, ratios, sizes shown in the drawings appended to this specification are provided in conjunction with the disclosure of this specification in order to facilitate understanding by those skilled in the art. They are not meant, in any ways, to limit the implementations of the present disclosure, and therefore have no substantial technical meaning. Without influencing the effects created and objectives achieved by the present disclosure, any modifications, changes or adjustments to the structures, ratios, or sizes are construed as falling within the scope covered by the technical contents disclosed herein. Meanwhile, terms such as “on,” “above,” “a,” “one” and the like, are for illustrative purposes, and are not meant to limit the scope implementable by the present disclosure. Any changes or adjustments made to the relative relationships, without substantially modifying the technical contents, are also to be construed as within the scope implementable by the present disclosure.

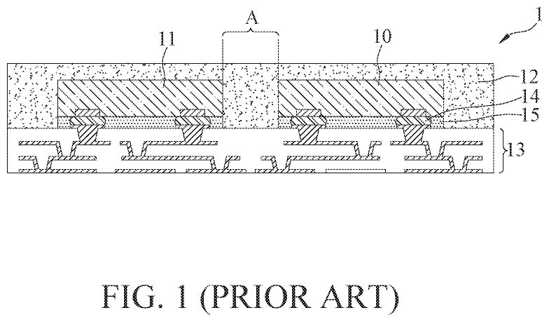

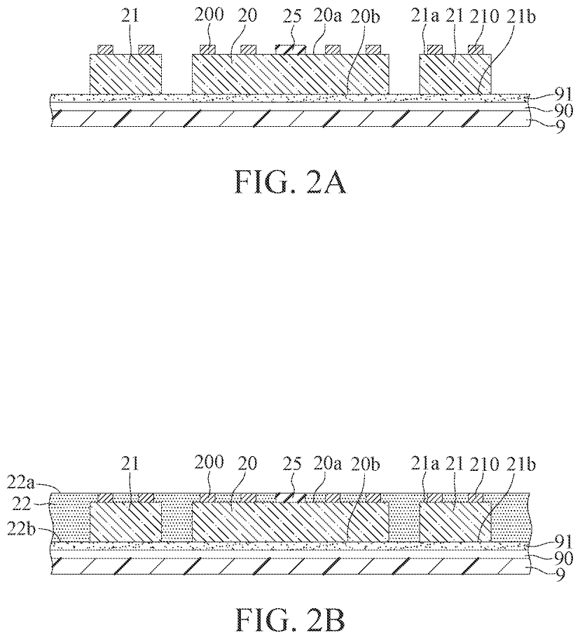

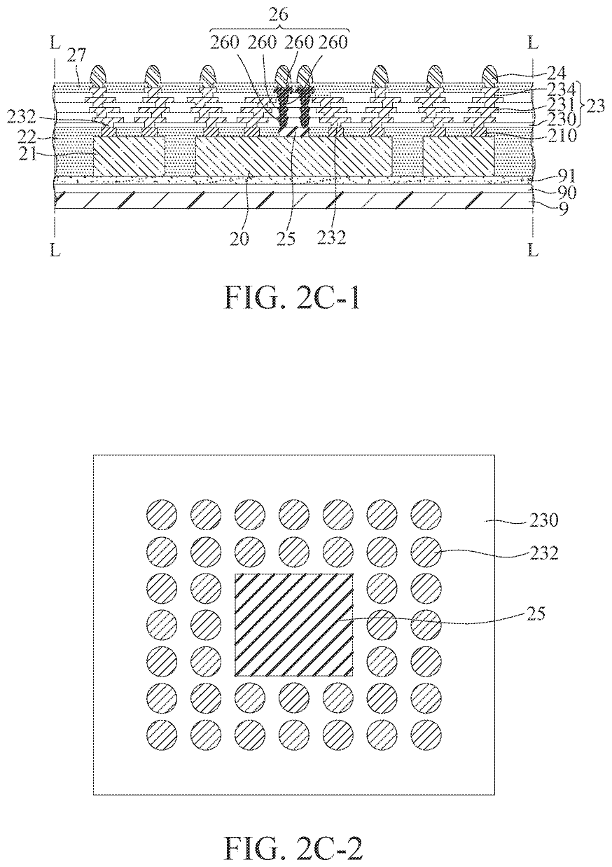

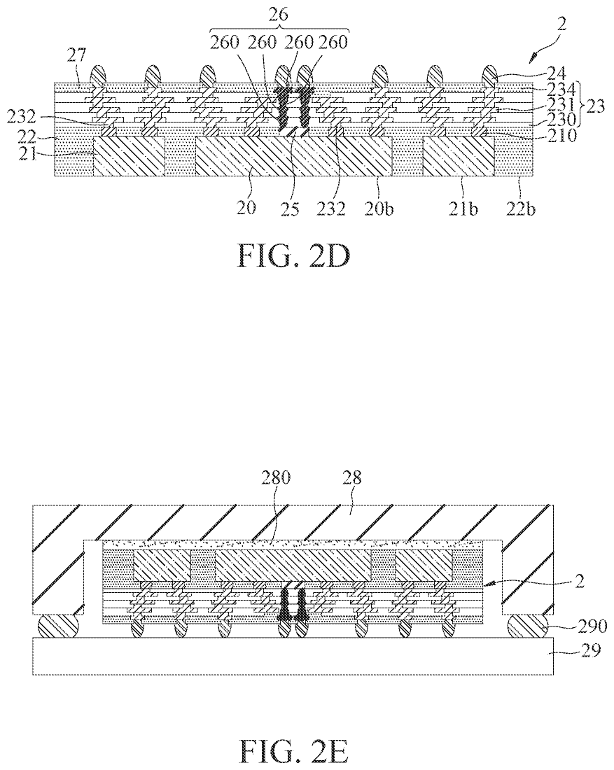

FIG. 2A, FIG. 2B, FIG. 2C-1 and FIG. 2D are schematic cross-sectional views illustrating a method of manufacturing an electronic package 2 according to the present disclosure.

As shown in FIG. 2A, a plurality of first electronic elements 20 and second electronic elements 21 spaced apart from each other are disposed on a carrier board 9 with full panel specification or wafer level specification.

The carrier board 9 is a board body made of semiconductor material (such as silicon or glass) or other board materials, on which an adhesive layer 90 and a release layer 91 are sequentially formed.

The first electronic element 20 is an active element, a passive element, a package structure, or a combination thereof. The active element is such as a semiconductor chip, and the passive element is such as a resistor, a capacitor, or an inductor.

In an embodiment, the first electronic element 20 is a semiconductor chip in the form of System-On-Chip (SoC) and has an active surface 20a and an inactive surface 20b opposing the active surface 20a. A plurality of electrode pads are formed on the active surface 20a, and a conductive bump 200 is formed on each of the electrode pads. Also, the first electronic element 20 is bonded to the release layer 91 with the inactive surface 20b thereof. For example, the conductive bumps 200 are metal pillars (such as copper pillars), solder material, or a combination thereof.

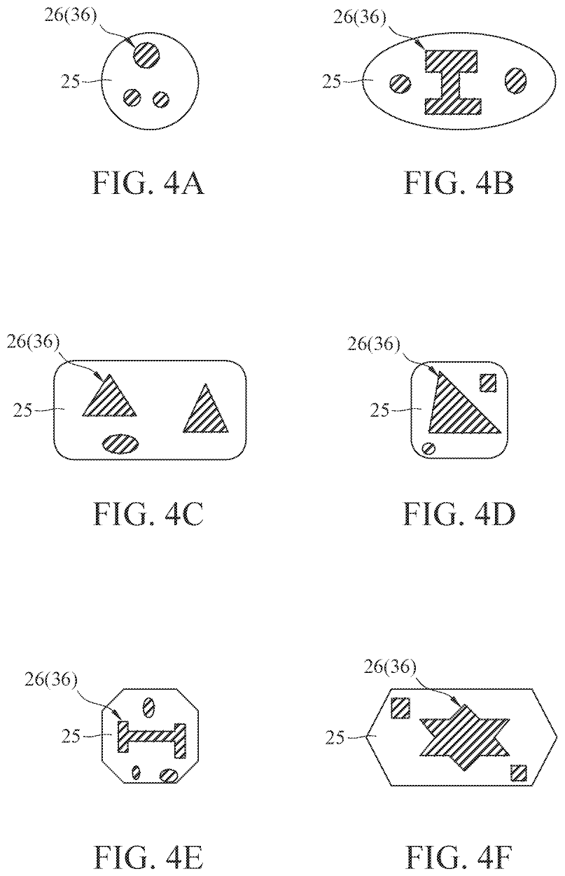

Furthermore, a heat dissipation body 25 can be disposed on the active surface 20a of the first electronic element 20 according to requirements. For example, the heat dissipation body 25 is in the form of a heat sink, and the shape of the heat dissipation body 25 can be designed according to requirements, such as various geometric shapes shown in FIG. 4A to FIG. 4F, and the present disclosure is not limited to as such. It should be understood that a portion of the electrode pads or conductive bumps of the first electronic element 20 can be used as heat dissipation pads or heat dissipation bumps without needing to add additional heat dissipation body 25 in the form of heat sink.

The second electronic element 21 is an active element, a passive element, a package structure, or a combination thereof. The active element may be a semiconductor chip, and the passive element may be a resistor, a capacitor, or an inductor.

In an embodiment, the second electronic element 21 is a semiconductor chip in the form of a memory and has an active surface 21a and an inactive surface 21b opposing the active surface 21a. A plurality of electrode pads are formed on the active surface 21a, and a conductive bump 210 is formed on each of the electrode pads. The second electronic element 21 is bonded to the release layer 91 with the inactive surface 21b thereof. For example, the conductive bumps 210 are metal pillars (such as copper pillars), solder material, or a combination thereof.

It should be understood that based on the chip form, a width of the first electronic element 20 is greater than a width of the second electronic element 21.

As shown in FIG. 2B, a packaging layer 22 is formed on the release layer 91 of the carrier board 9 to cover the first electronic element 20 and the second electronic element 21, wherein the packaging layer 22 has a first surface 22a and a second surface 22b opposing the first surface 22a, so that the packaging layer 22 is bonded onto the release layer 91 with the second surface 22b thereof.

In an embodiment, the packaging layer 22 is made of an insulating material, such as polyimide (PI), dry film, epoxy resin, molding compound, or other suitable packaging materials. For example, the packaging layer 22 is formed on the carrier board 9 in a manner of lamination or molding.

Moreover, a portion of the material of the first surface 22a of the packaging layer 22 can be removed by a flattening/leveling process or a thinning process, so that the heat dissipation body 25, the conductive bumps 200 on the active surface 20a of the first electronic element 20 and the conductive bumps 210 on the active surface 21a of the second electronic element 21 are coplanar with the first surface 22a of the packaging layer 22, so that the heat dissipation body 25 and the conductive bumps 200, 210 (or the active surface 20a of the first electronic element 20 and the active surface 21a of the second electronic element 21) are exposed from the packaging layer 22. For example, when forming the packaging layer 22 on the carrier board 9, the active surface 20a of the first electronic element 20 and the active surface 21a of the second electronic element 21 and the conductive bumps 200, 210 thereon are covered by the packaging layer 22, and then a portion of the material of the packaging layer 22 is removed by grinding or cutting (a portion of the material of the heat dissipation body 25, a portion of the material of each of the conductive bumps 200 and a portion of the material of each of the conductive bumps 210 can also be removed at the same time according to requirements), so that the heat dissipation body 25 and the conductive bumps 200, 210 (or the active surface 20a of the first electronic element 20 and the active surface 21a of the second electronic element 21) are flush with the first surface 22a of the packaging layer 22.

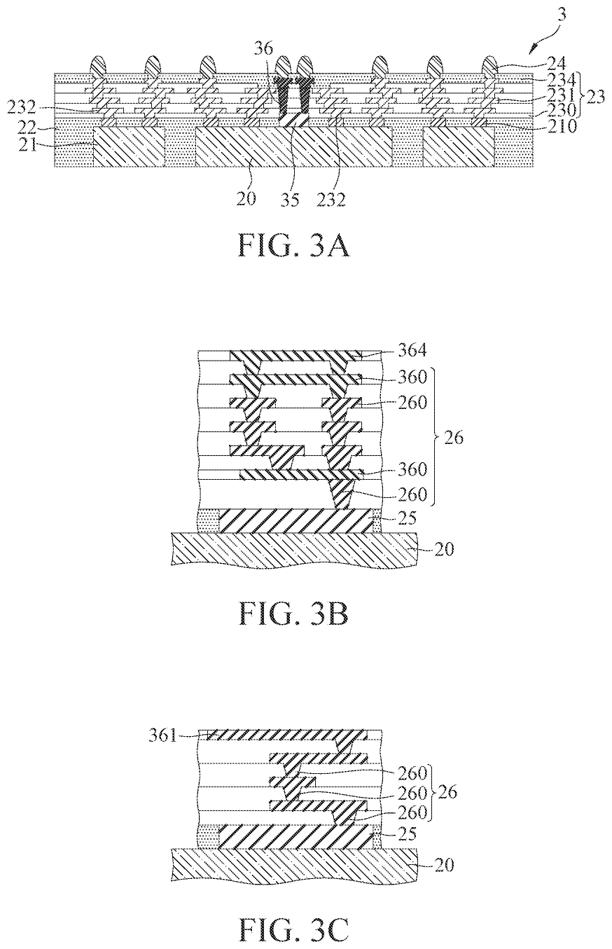

It should be understood that, in an electronic package 3 shown in FIG. 3A, the thinness of the first surface 22a of the packaging layer 22 can be designed according to requirements, so that a heat dissipation body 35 protrudes from the first surface 22a of the packaging layer 22.

As shown in FIG. 2C-1, a circuit structure 23 with a heat dissipation portion 26 is formed on the packaging layer 22, so that the circuit structure 23 is electrically connected to the conductive bumps 200 of the first electronic element 20 and the conductive bumps 210 of the second electronic element 21, and the heat dissipation portion 26 is thermally connected to the heat dissipation body 25 (or the active surface 20a of the first electronic element 20).

In an embodiment, the circuit structure 23 includes at least one insulating layer 230, a circuit layer 231 formed on the insulating layer 230, and a plurality of conductive blind vias 232 formed in the insulating layer 230 and electrically connected to the conductive bumps 200, 210 and the circuit layer 231, wherein an insulating protective layer 27 (such as a solder-resist layer) can be formed on the outermost insulating layer 230 of the circuit structure 23, so that the outermost circuit layer 231 is partially exposed from the insulating protective layer 27 to serve as electrical contact pads 234 for connecting a plurality of conductive elements 24 containing solder material. For example, the circuit structure 23 is formed in a manner of fabricating a redistribution layer (RDL), wherein the material for forming the circuit layer 231 is copper, and the material for forming the insulating layer 230 is polybenzoxazole (PBO), polyimide (PI), prepreg (PP), or other dielectric materials.

Furthermore, at the innermost insulating layer 230, the conductive blind vias 232 surround the heat dissipation body 25, as shown in FIG. 2C-2.

Also, the heat dissipation portion 26 includes a plurality of stacked heat dissipation pillars 260 to contact the heat dissipation body 25 (or the active surface 20a of the first electronic element 20), wherein the circuit structure 23 is penetrated through by the heat dissipation portion 26. For example, when fabricating the conductive blind vias 232, blind vias for heat dissipation are also fabricated, so that a metal material is filled in the blind vias for heat dissipation to serve as the heat dissipation pillars 260, and the conductive elements 24 can also be provided on the outermost heat dissipation pillars 260. It should be understood that the via shape of the heat dissipation pillars 260 can be designed according to requirements, such as various geometric shapes shown in FIG. 4A to FIG. 4F, which can be the same or different from the shape of the heat dissipation body 25, and the present disclosure is not limited to as such.

In addition, in another embodiment, in the electronic package 3 shown in FIG. 3A, a heat dissipation portion 36 can also be a single heat dissipation pillar, which is drilled after the outermost circuit layer 231 is fabricated to make a heat dissipation pillar with deeper depth.

Further, as shown in FIG. 3B, the heat dissipation portion 26 can also cooperate with the fabrication of the circuit layer to form a heat dissipation layer 360 together, so that the heat dissipation pillars 260 can be thermally connected by the heat dissipation layer 360, and the heat dissipation layer 360 can be connected to a heat dissipation pad 364 such as an electrical contact pad at the outermost layer to bond with conductive elements; or, as shown in FIG. 3C, the heat dissipation portion 26 cooperates with the fabrication of the circuit layer, so that the heat dissipation portion 26 is connected to a ground wire 361 of the circuit structure. Therefore, there are various aspects of the heat dissipation portion, which can be designed according to requirements, and are not limited to the above.

As shown in FIG. 2D, the carrier board 9 and the adhesive layer 90 and the release layer 91 thereon are removed to expose the second surface 22b of the packaging layer 22, the inactive surface 20b of the first electronic element 20 and the inactive surface 21b of the second electronic element 21, and a singulation process is performed along a cutting path L shown in FIG. 2C-1 to obtain multiple electronic packages 2.

In an embodiment, as shown in FIG. 2E, in the subsequent manufacturing process, the electronic package 2 can be disposed on an electronic device 29 such as a circuit board via the conductive elements 24. Further, a heat dissipation frame 28 can be disposed on the electronic device 29 via an adhesive material 290 such as solder or glue, and the heat dissipation frame 28 is in contact with and bonded to the second surface 22b of the packaging layer 22, the inactive surface 20b of the first electronic element 20 and the inactive surface 21b of the second electronic element 21 via a heat conduction layer 280 that serves as a thermal interface material (TIM).

Furthermore, if the heat dissipation body 35 is protruded from the first surface 22a of the packaging layer 22, the electronic package 3 as shown in FIG. 3A will be obtained, and the circuit structure 23 is free from being penetrated through by the heat dissipation portion 36.

Therefore, in the manufacturing method of the present disclosure, the circuit structure 23 is designed with the heat dissipation portion 26, 36, so that the heat dissipation portion 26, 36 can be thermally connected to the active surface 20a of the first electronic element 20, so as to strengthen the heat dissipation effect of the first electronic element 20. Therefore, compared with the prior art, when the first electronic element 20 has a high computing function, the heat energy generated during the operation of the first electronic element 20 will be quickly dissipated to the outside via the heat dissipation portion 26, 36, so as to avoid the problem of affecting the operation of the second electronic element 21 due to the overheating of the packaging layer 22.

The present disclosure further provides an electronic package 2, 3, comprising: a packaging layer 22, a first electronic element 20 embedded in the packaging layer 22, a second electronic element 21 embedded in the packaging layer 22, and a circuit structure 23 disposed on the packaging layer 22.

The second electronic element 21 embedded in the packaging layer 22 is spaced apart from the first electronic element 20.

The circuit structure 23 is electrically connected to the first electronic element 20 and the second electronic element 21, wherein the circuit structure 23 has a heat dissipation portion 26, 36 thermally connected to the first electronic element 20.

In one embodiment, the circuit structure 23 includes at least one insulating layer 230, a circuit layer 231 formed on the insulating layer 230 and a plurality of conductive blind vias 232 formed in the insulating layer 230 and electrically connected to the circuit layer 231 and the first electronic element 20.

In one embodiment, the heat dissipation portion 26 includes a plurality of stacked heat dissipation pillars 260.

In one embodiment, the heat dissipation portion 36 is a single heat dissipation pillar.

In one embodiment, the heat dissipation portion 26 further includes at least one heat dissipation pillar 260 and at least one heat dissipation layer 360 thermally connected to the heat dissipation pillar 260.

In one embodiment, the circuit structure 23 has a ground wire 361 connected to the heat dissipation portion 26.

In one embodiment, the circuit structure 23 is penetrated through by the heat dissipation portion 26.

In one embodiment, the circuit structure 23 is free from being penetrated through by the heat dissipation portion 36.

In one embodiment, the first electronic element 20 is provided with a heat dissipation body 25, 35 corresponding to the heat dissipation portion 26, 36. For example, the heat dissipation body 25, 35 is a heat sink.

In view of the above, in the electronic package and the manufacturing method thereof according to the present disclosure, the circuit structure is designed with a heat dissipation portion, so that the heat dissipation portion is thermally connected to the first electronic element to strengthen the heat dissipation effect of the first electronic element. Therefore, when the first electronic element has a high computing function, the heat energy generated during the operation of the first electronic element can be quickly dissipated to the outside via the heat dissipation portion, so as to avoid the problem of affecting the operation of the second electronic element due to overheating of the packaging layer.

The above embodiments are provided for illustrating the principles of the present disclosure and its technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. An electronic package, comprising:
a packaging layer;
a first electronic element embedded in the packaging layer;
a second electronic element embedded in the packaging layer and spaced apart from the first electronic element; and
a circuit structure disposed on the packaging layer and electrically connected to the first electronic element and the second electronic element, wherein the circuit structure has a heat dissipation portion thermally connected to the first electronic element.

2. The electronic package of claim 1, wherein the circuit structure includes an insulating layer, a circuit layer formed on the insulating layer, and a plurality of conductive blind vias formed in the insulating layer and electrically connected to the circuit layer and the first electronic element.

3. The electronic package of claim 1, wherein the heat dissipation portion includes a plurality of heat dissipation pillars stacked on each other.

4. The electronic package of claim 1, wherein the heat dissipation portion is a single heat dissipation pillar.

5. The electronic package of claim 1, wherein the heat dissipation portion further comprises at least one heat dissipation pillar and at least one heat dissipation layer thermally connected to the heat dissipation pillar.

6. The electronic package of claim 1, wherein the circuit structure has a ground wire connected to the heat dissipation portion.

7. The electronic package of claim 1, wherein the circuit structure is penetrated through by the heat dissipation portion.

8. The electronic package of claim 1, wherein the circuit structure is free from being penetrated through by the heat dissipation portion.

9. The electronic package of claim 1, wherein the first electronic element is provided with a heat dissipation body corresponding to the heat dissipation portion.

10. The electronic package of claim 9, wherein the heat dissipation body is a heat sink.

11. A method of manufacturing an electronic package, the method comprising:
embedding a first electronic element and a second electronic element in a packaging layer in a manner of being spaced apart from each other; and
forming a circuit structure on the packaging layer, wherein the circuit structure is electrically connected to the first electronic element and the second electronic element, and the circuit structure has a heat dissipation portion thermally connected to the first electronic element.

12. The method of claim 11, wherein the circuit structure includes an insulating layer, a circuit layer formed on the insulating layer, and a plurality of conductive blind vias formed in the insulating layer and electrically connected to the circuit layer and the first electronic element.

13. The method of claim 11, wherein the heat dissipation portion includes a plurality of heat dissipation pillars stacked on each other.

14. The method of claim 11, wherein the heat dissipation portion is a single heat dissipation pillar.

15. The method of claim 11, wherein the heat dissipation portion further comprises at least one heat dissipation pillar and at least one heat dissipation layer thermally connected to the heat dissipation pillar.

16. The method of claim 11, wherein the circuit structure has a ground wire connected to the heat dissipation portion.

17. The method of claim 11, wherein the circuit structure is penetrated through by the heat dissipation portion.

18. The method of claim 11, wherein the circuit structure is free from being penetrated through by the heat dissipation portion.

19. The method of claim 11, wherein the first electronic element is provided with a heat dissipation body corresponding to the heat dissipation portion.

20. The method of claim 19, wherein the heat dissipation body is a heat sink.
